(19) United States
(12) Patent Application Publication
(10) Pub. No.: US 2025/0225284 A1
(43) Pub. Date: Jul. 10, 2025

(54) COMPUTING PLATFORM FOR RENOVATION

(71) Applicant: RenoScope, LLC, Marietta, GA (US)

(72) Inventor: Troy Rushing, Marietta, GA (US)

(73) Assignee: RenoScope, LLC, Marietta, GA (US)

(21) Appl. No.: 18/405,737

(22) Filed: Jan. 5, 2024

(51) Int. Cl. G06F 30/13

(52) U.S. Cl. CPC G06F 30/13

(57) ABSTRACT

A method to facilitate building renovation is disclosed. The method includes obtaining an indication to renovate a building portion from a user. The method further includes obtaining a first plurality of images associated with the building portion from a first user device. Responsive to obtaining the first plurality of images, the method includes identifying building portion dimensions based on the first plurality of images. The method further includes identifying job portions associated with the building portion based on the first plurality of images and generating a relative job portion renovation order in response to job portion identification. In addition, the method includes transmitting information associated with the job portions to at least a third party device based on the relative renovation order. The transmitted information includes the building portion dimensions.

### TECHNICAL FIELD

The present disclosure relates to a system and method to facilitate renovation of a building, and more particularly, to a computing platform to inspect building portions, estimate renovation work and facilitate building portion renovation.

### BACKGROUND

Buildings may require repair or renovation work from time to time. For example, a building may get damaged and a building owner may repair damaged building portions to restore the building condition. In addition, a building owner may renovate the building to change building design or look.

Building renovation is a complex process that requires damaged building portions' evaluation, determination of required renovation process, management of contractors/workers, etc. Typically, the building owner requests multiple contractors to inspect the building and provide cost estimation for the renovation. The contractors may visit the building for inspection, estimate renovation work, measure dimensions, calculate costs and provide quotes to the building owner. The building owner may compare quotes from the contractors and may assign renovation job to a contractor that fits the owner's budget.

Typically, the process of receiving quotes and selecting the contractor(s) may be time-consuming and may require multiple interactions between the building owner and the contractors. In addition, building portion dimension measurement and renovation cost estimation may be prone to human errors. Therefore, the contractors may provide incorrect quotes or may revise quotes if the building portion dimension measurement is incorrect. This may cause inconvenience for the building owner, especially if the contractors revise the quotes midway during the renovation process. Furthermore, measuring building portions may be time consuming and may pose logistical challenges for the contractors.

Thus, there exists a need in the industry for an efficient and transparent renovation system that can inspect building portions, estimate renovation work and facilitate renovation of building portions.

It is with respect to these and other considerations that the disclosure made herein is presented.

### BRIEF DESCRIPTION OF THE DRAWINGS

The detailed description is set forth with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 depicts an example environment in which techniques and structures for providing the systems and methods disclosed herein may be implemented.

FIG. 2 depicts an example renovation platform in accordance with the present disclosure.

FIG. 3 depicts a flow diagram of an example method for facilitating building renovation in accordance with the present disclosure.

### DETAILED DESCRIPTION

### Overview

The present disclosure is directed towards a computing platform to facilitate renovation of a building. A user may access the platform and submit a request to renovate a building or building portion(s). The building portion(s) may include, for example, a kitchen, a building roof, a washroom, a balcony, an exterior building surface and the like. In addition to submitting the renovation request, the user or a third party (e.g., a computing platform representative) may capture a plurality of building portion images by using a user device (or camera/drone) and transmit the images to the platform by using the user device. The plurality of building portion images may include photographs, videos, augmented or virtual reality images and/or the like, of the building portions to be renovated. The platform may receive the building portion images and generate a building portion three-dimensional (3D) model, which may enable the platform to identify building portion dimensions. Further, the platform may identify job portions (along with a relative job portion order) for renovating the building portions based on the plurality of building portion images. For example, to renovate the kitchen, the platform may identify the job portions as carpentry, painting, electrical work and the like. The relative job portion order may indicate, for example, that the electrical and the carpentry work may need to be completed before the painting work. In response to identifying the job portions and the relative job portion order, the platform may transmit job portion information (including the building portion dimensions) to a plurality of contractors to receive quotes and proposed timelines to complete the job portions. Based on the received quotes, the platform may select contractor(s) for the job portions.

In some aspects, the platform may share the received quotes from the contractors to the user and the user may select the contractor(s) for the job portions. In further aspects, the platform may first send the identified job portions to the user for confirmation or shortlisting, and the user may remove (or add) job portions from the job portions identified by the platform. In this case, the platform may transmit job portion information associated with the job portions shortlisted by the user to the plurality of contractors for receiving quotes.

In additional aspects, the user may share target building portion images along with the request for building portion renovation. The target building portion images may indicate a desired building portion look/design that the user may wish to consider for renovation. In this case, the platform may compare the received plurality of building portion images with the target building portion images and may accordingly identify job portions for building portion renovation.

The present disclosure describes a renovation computing platform that enables building portion dimension measurement and job portion identification. Since the platform measures the building portion dimensions, probability of human error in measurement is reduced. Further, the platform identifies the relative job portion order, which facilitates in providing transparency to the user and the contractors on the completion timelines of different job portions.

These and other advantages of the present disclosure are provided in detail herein.

### Illustrative Embodiments

The disclosure will be described more fully hereinafter with reference to the accompanying drawings, in which example embodiments of the disclosure are shown, and not intended to be limiting.

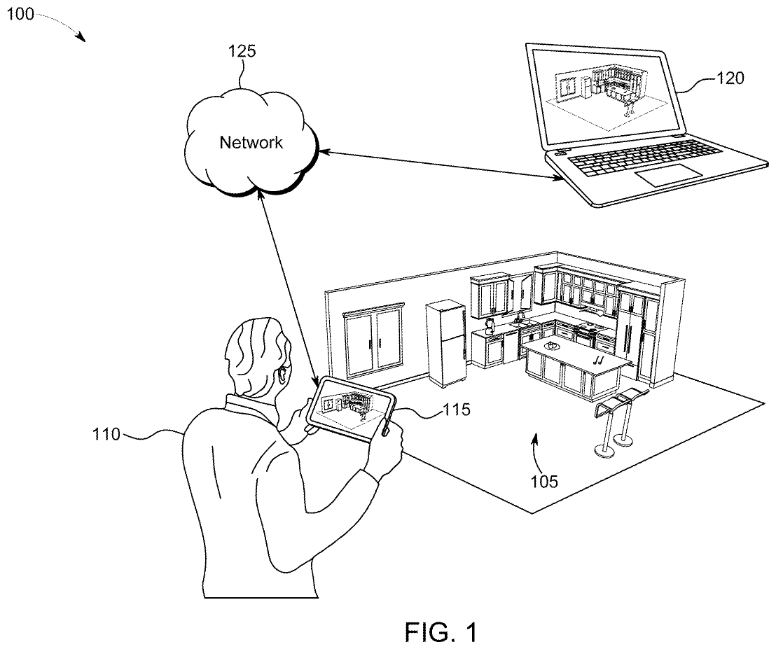

FIG. 1 depicts an example environment 100 in which techniques and structures for providing the systems and methods disclosed herein may be implemented. The environment 100 may include a building portion 105 that may require renovation. The building portion 105 may be associated with a building (not shown). The building may be a residential or a commercial building and the building portion 105 may be a part of the residential or the commercial building that may require renovation. The building portion 105 may be, for example, a kitchen (as shown in FIG. 1), a living room, a bedroom, a washroom, a roof, a building exterior surface, an office space and the like. In some aspects, the building portion 105 may include one or more objects such as cabinets, doors, windows, furniture, appliances and the like.

In accordance with some aspects, a user 110 may capture building portion images or videos, which may facilitate the user 110 to determine the scope/extent of renovation that may be required for the building portion 105. The user 110 may be a building owner, a renovation contractor, a bank representative funding the renovation and/or the like. In some aspects, the user 110 may use a user device 115 to capture the building portion images or videos. The user device 115 may be a mobile phone, a high-definition camera, a laptop, a tablet and the like. In other aspects, an unmanned aerial vehicle (not shown), such as a drone, may capture the building portion images or videos. In some aspects, the user 110 may select a relevant device from the user device 115 and the unmanned aerial vehicle to capture the images/videos based on building portion(s) to be renovated. In other words, the user 110 may determine resources required for capturing the images/videos, based on the specific building portions to be renovated. For example, the user 110 may use a handheld camera or a mobile phone if the building portion 105 is the kitchen and may use the unmanned aerial vehicle if the building portion 105 is the roof or the building exterior surface.

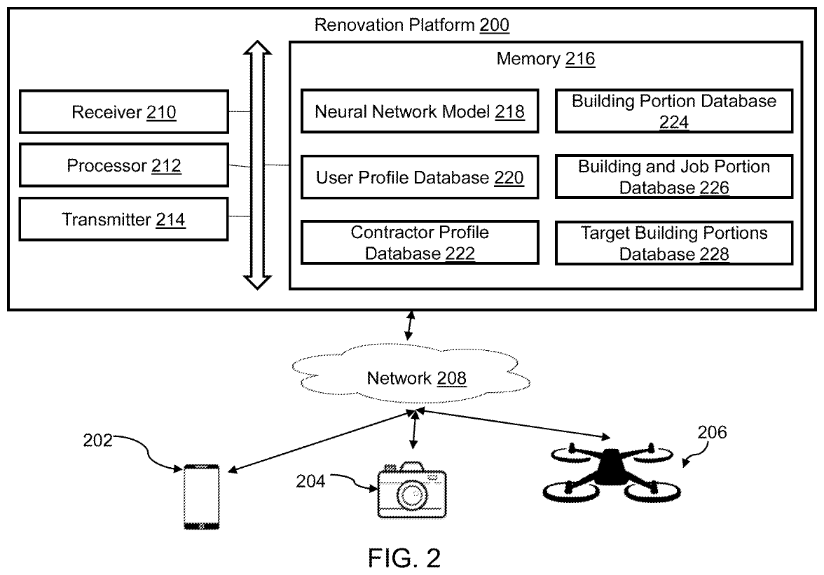

In some aspects, the user 110 may use the captured building portion images or videos to reconstruct a building portion three-dimensional (3-D) model that may assist the user 110 to accurately measure building portion dimensions. Based on building portion measurement, the user 110 may determine a renovation scope/extent, which may facilitate in estimating a renovation cost. The process or determining the renovation scope/extent is described in conjunction with FIG. 2.

In some aspects, the user device 115 may communicatively couple with a server or a computing device 120, via one or more networks 125 (or a network 125). Specifically, the user device 115 (or the unmanned aerial vehicle) may transmit the captured building portion images or videos to the computing device 120 via the network 125.

The network 125 may be, for example, a communication infrastructure in which the connected devices discussed in various embodiments of this disclosure may communicate. The network 125 may be and/or include the Internet, a private network, public network or other configuration that operates using any one or more known communication protocols such as, for example, transmission control protocol/Internet protocol (TCP/IP), Bluetooth®, BLE®, Wi-Fi based on the Institute of Electrical and Electronics Engineers (IEEE) standard 802.11, UWB, and cellular technologies such as Time Division Multiple Access (TDMA), Code Division Multiple Access (CDMA), High Speed Packet Access (HSPDA), Long-Term Evolution (LTE), Global System for Mobile Communications (GSM), and Fifth Generation (5G), to name a few examples.

In response to receiving the captured images or videos from the user device 115, the computing device 120 may be configured to generate the building portion 3D model based on the images/videos and precisely determine building portion dimensions by using the 3D model. For example, the computing device 120 may generate a kitchen 3D model, identify dimensions of walls, cabinets, doors, windows, etc., located in the kitchen and store the model along with the dimensions in a computing device memory (not shown).

In further aspects, the computing device 120 may be configured to analyze the 3D model and the captured images/videos, and identify renovation requirements (e.g., identify one or more job portions) for the kitchen. For example, the computing device 120 may identify that job portions such as plumbing, roof framing, electrical work, flooring, carpentry and the like, may be required to renovate the kitchen.

The computing device 120 may be further configured to transmit, via the network 125, quotation requests to different contractors based on the job portion identification. In particular, the computing device 120 may match the identified job portions with contractor profiles (that may be stored in the computing device memory) and identify relevant contractors who may perform respective job portions. The computing device 120 may send the quotation requests to relevant contractors' user devices, along with respective images/videos (e.g., images of floors to contractors associated with flooring) and building portion dimensions.

In one or more aspects, the computing device 120 may be configured to receive quotations from the contractors and assign the job portions to one or more contractors to renovate the building portion 105 based on the received quotations. In other aspects, the computing device 120 may transmit the received quotations to the user device 115 and the user 110 may select the one or more contractors to renovate the building portion 105 based on the quotations and the contractor profiles.

In some aspects, the computing device 120 may be an Artificial Intelligence (AI)-based system that may include a neural network model (not shown). The neural network model may be a trained or unsupervised neural network model that may analyze the information (e.g., images or videos) received from the user device 115 (or the unmanned aerial vehicle) using machine learning and image processing, which may facilitate building renovation (specifically, building portion 3D model generation and building portion dimension determination).

In one or more aspects, the neural network model may include electronic data, which may be implemented, for example, as a software component, and may rely on code databases, libraries, scripts, or other logic or instructions for execution of a neural network algorithm by a renovation platform processor (not shown in FIG. 1). The neural network model may be implemented as code and routines configured to enable a computing device, such as the computing device 120, to perform one or more operations. In some aspects, the neural network model may be implemented using hardware including a processor, a microprocessor, a field-programmable gate array (FPGA), or an application-specific integrated circuit (ASIC). In other aspects, the neural network model 112 may be implemented by using a combination of hardware and software.

Examples of the neural network model may include, but are not limited to, a deep neural network (DNN), a convolutional neural network (CNN), a recurrent neural network (RNN), a CNN-recurrent neural network (CNN-RNN), R-CNN, Fast R-CNN, Faster R-CNN, an artificial neural network (ANN), a Long Short Term Memory (LSTM) network based RNN, CNN+ANN, LSTM+ANN, a gated recurrent unit (GRU)-based RNN, a fully connected neural network, a deep Bayesian neural network, a Generative Adversarial Network (GAN), and/or a combination of such networks. In some aspects, the neural network model may include numerical computation techniques using data flow graphs. In one or more aspects, the neural network model may be based on a hybrid architecture of multiple Deep Neural Networks (DNNs).

In operation, the user 110 may create an account (e.g., a user account) on a renovation application that may be installed on the computing device 120, via the user device 115, when the user 110 accesses the renovation application for a first time. The user 110 may provide user information to the renovation application while creating the account. The user information may include, for example, user profile information and user requirements. The user profile information may include, for example, user name, home/building address, contact details and/or the like. The user requirements may include building type (residential or commercial), user budget, building portions to be renovated, tentative start and finish timelines, specific renovation instructions, information of material to use for renovation and/or the like.

Responsive to receiving the user information, the renovation application may create the user account. The user 110 may access, via the user device 115, the renovation application when the renovation application creates the user account.

In some aspects, the user 110 may request and manage one or more renovation projects by using the user account on the renovation application. For example, by using the renovation application, the user 110 may request building portion renovation, receive estimated renovation cost, identify job portions, manage contractors (such as receive quotes and contractor profiles, manage contractor bidding, select a contractor and assign renovation work), store renovation inspection details, manage inspection, track renovation progress and/or the like.

In further aspects, the user 110 may transmit the above-mentioned details to the bank representative who may be funding the building portion renovation. The bank representative may release funds for the renovation based on, for example, the renovation progress or renovation inspection details. In other aspects, the bank representative may also access the renovation application directly and fetch the renovation details mentioned above, which may facilitate the bank representative to decide whether to release fresh funds for the renovation project.

FIG. 2 depicts an example renovation platform 200 (or a renovation system) in accordance with the present disclosure. In some aspects, the renovation platform 200 may be same as the computing device 120 and may have the renovation application (described in FIG. 1) installed on the renovation platform 200. The renovation platform 200 may communicatively connect with a user device 202, an image capturing device 204 and an unmanned aerial device 206, via a network 208 (same as the network 125).

The user device 202 may be same as the user device 115. For example, the user device 202 may be a mobile phone, a laptop, a tablet and the like. A user (e.g., the user 110) may access the renovation platform 200 by using the user device 202.

Further, the image capturing device 204 may include a camera (including a high-definition camera) and the unmanned aerial device 206 may include a drone. In some aspects, the unmanned aerial device 206 may also include a camera that may be configured to capture images/videos of objects or buildings.

The renovation platform 200 may include a plurality of components including, but not limited to, a receiver 210, a processor 212, a transmitter 214 and a memory 216. In some aspects, the memory 216 may store programs in code and/or store data for performing various renovation platform operations in accordance with the present disclosure. Specifically, the processor 212 may be configured and/or programmed to execute computer-executable instructions stored in the memory 216 for performing various renovation platform operations in accordance with the present disclosure. Consequently, the memory 216 may be used for storing code and/or data code and/or data for performing operations in accordance with the present disclosure.

In one or more aspects, the processor 212 may be disposed in communication with one or more memory devices (e.g., the memory 216 and/or one or more external databases (not shown in FIG. 2)). The memory 216 can include any one or a combination of volatile memory elements (e.g., dynamic random-access memory (DRAM), synchronous dynamic random access memory (SDRAM), etc.) and can include any one or more nonvolatile memory elements (e.g., erasable programmable read-only memory (EPROM), flash memory, electronically erasable programmable read-only memory (EEPROM), programmable read-only memory (PROM), etc.).

The memory 216 may be one example of a non-transitory computer-readable medium and may be used to store programs in code and/or to store data for performing various operations in accordance with the disclosure. The instructions in the memory 216 can include one or more separate programs, each of which can include an ordered listing of computer-executable instructions for implementing logical functions. For example, the memory 216 may include a neural network model 218 that may facilitate the renovation platform 200 to assist the user 110 in renovation of a building.

In further aspects, the memory 216 may include a plurality of databases including, but not limited to, a user profile database 220, a contractor profile database 222, a building portion database 224, a building and job portion database 226 and a target building portions database 228. In one or more aspects, the processor 212 may use, via the neural network model 218, the information stored in the memory databases and assist the user in building renovation.

In some aspects, the receiver 210 may be configured to receive user information from the user device 202 via the network 208. As described in conjunction with FIG. 1, the user information may include, for example, user profile information and user requirements. The user profile information may include, for example, user name, home/building address, contact details and/or the like. The user requirements may include building type (residential or commercial), renovation budget, building portions to be renovated, tentative start and completion timelines for the renovation and/or the like.

Responsive to receiving the user information, the receiver 210 may send the user information to the memory 216, which in turn may store the received information in the user profile database 220.

In further aspects, the receiver 210 may be configured to receive contractor information from external user devices or servers (not shown in FIG. 2), via the network 208. The external user devices or servers may be associated with one or more contractors who may provide services required for building renovation. For example, the one or more contractors may include plumbers, electricians, carpenters, firms that may support building renovation and the like. In some aspects, the one or more contractors may access the renovation platform 200 and share the contractor information, which may enable the renovation platform 200 to assist the user 110 in building renovation. The contractor information may include details of services provided by the contractor, contractor insurance information, licensing information, bond information, years in business, history, contractor reviews and/or the like.

Responsive to receiving the contractor information from the external user devices or servers, the receiver 210 may send the information to the memory 216. The memory 216 may store the contractor information in the contractor profile database 222.

The receiver 210 may be further configured to receive an indication from the user 110 to renovate a building or building portion(s). For example, the user 110 may send a request to the receiver 210 for building renovation via the user device 202 and the network 208. In some aspects, the user 110 may send the request to renovate a complete building (e.g., a residential or a commercial building). In other aspects, the user 110 may send the request to renovate one or more building portions (such as kitchen, living room and the like) within the building.

Responsive to receiving the request for renovation, the receiver 210 may additionally receive, via the network 208, a first plurality of images associated with the building or building portions to be renovated. In some aspects, the receiver 210 may receive the first plurality of images from the user device 202, the image capturing device 204, the unmanned aerial device 206 and/or a combination thereof. For example, responsive to receiving the request for renovation, the renovation platform 200 may send a request, via the transmitter 214, to the user device 202 to provide the first plurality of images. The user 110 may then send the first plurality of images to the receiver 210 by using the user device 202 and/or the image capturing device 204. In other aspects, a different user (e.g., a representative associated with the renovation platform 200 or a renovation contractor) may capture the first plurality of images by using the image capturing device 204 and/or the unmanned aerial device 206, and may send the images to the receiver 210.

The first plurality of images may include building portion photographs, videos, augmented/virtual reality images and/or a combination thereof. The renovation platform 200, specifically the processor 212, may use the first plurality of images to generate a building portion 3D scan/model, which may assist the processor 212 to accurately analyze building portion attributes. The attributes may be dimensions of walls, windows, doors, cabinets and other objects located in the building or building portions.

Responsive to receiving the first plurality of images, the receiver 210 may send the first plurality of images to the memory 216, which may store the images in the building portion database 224. The building portion database 224 may further store the building portion attributes that the processor 212 may identify from the first plurality of images.

In additional aspects, along with sending the first plurality of images, the user device 202 may transmit target building portion images to the receiver 210. In other words, the user 110 may additionally send a second plurality of target building portion images to the receiver 210. The second plurality of target building portion images may include sample images or photographs according to which the user 110 may want to renovate the building/building portion. For example, the user 110 may capture images of a neighbor's kitchen and may share the images to the receiver 210, which may indicate to the renovation platform 200 that the user 110 may want the user's kitchen to look like the kitchen included in the captured images, post renovation.

Responsive to receiving the second plurality of target building portion images, the receiver 210 may send the images to the target building portions database 228 for storage purpose.

In further aspects, the receiver 210 may be configured to receive information associated with a plurality of job portions that may typically correspond to renovation of different building portions. The receiver 210 may receive the information associated with the plurality of job portions from external devices or servers (not shown in FIG. 2) that may pre-store the information. The information associated with the plurality of job portions may include a mapping of each building portion with one or more associated job portions. As an example, one or more job portions associated with kitchen renovation may include plumbing, roof framing, electrical work, flooring, carpentry and the like. Similarly, job portions associated with washroom renovation may include sanitary work, flooring, plumbing and the like.

In further aspects, the information associated with the plurality of job portions may include a relative job portion order for each building portion renovation. The relative order may include logical steps to renovate respective building or building portions. In other words, the relative order may include a preset priority renovation order associated with the renovation portion. For example, the relative order may indicate that carpentry work may be performed before painting work or electrical work may be performed before flooring work and the like.

Responsive to receiving the information associated with a plurality of job portions, the receiver 210 may send the information to the building and job portion database 226 for storage purpose.

In some aspects, the processor 212 may be configured to obtain information received by the receiver 210 and/or access the memory 216 (specifically the memory databases described above) to analyze the stored information, which may facilitate the processor 212 to assist the user 110 in building renovation. For example, the processor 212 may be configured to obtain the indication/request to renovate the building or building portion(s) when the receiver 210 receives the indication from the user device 202. Responsive to obtaining the indication from the receiver 210, the processor 212 may obtain or fetch the first plurality of images from the building portion database 224.

The processor 212 may be further configured to analyze the obtained first plurality of images and calculate a quality score for the building portion based on the first plurality of images. The quality score may indicate a first plurality of images' quality and/or comprehensiveness, which may facilitate the processor 212 to accurately analyze the building portion by using the first plurality of images. For example, the processor 212 may determine whether the first plurality of images captures all building portion views for the building portion to be renovated. As further example, if the building portion is kitchen, the processor 212 may determine whether the first plurality of images includes views of all kitchen walls, doors, cabinets, appliances, etc. In some aspects, the processor 212 may determine whether the first plurality of images includes all building portion views by counting a number of distinct images included in the first plurality of images. For example, if a count of images is less than a predefined image threshold, the processor 212 may determine that the first plurality of images may not include all building portion views.

The processor 212 may also determine an image clarity/resolution (e.g., by determining number of pixels in the images) for the first plurality of images. Based on the number of views and image clarity/resolution, the processor 212 may provide the quality score to the building portion. In a scenario when the images capture all or most of building portion views and the image clarity is good (e.g., when pixel count is greater than a predefined pixel threshold), the processor 212 may calculate/assign a high quality score (e.g., 95% or above) to the building portion. Alternatively, when the processor 212 determines that the images do not capture all the views, the processor 212 may calculate a low quality score (e.g., less than 75%).

Responsive to calculating the quality score, the processor 212 may compare the calculated score with a quality score threshold that may be stored in the memory 216 (e.g., in the building portion database 224). When the calculated quality score is less than the quality score threshold, the processor 212 may transmit, via the transmitter 214, another request to the user device 202 to provide additional building portion images and/or images with better resolution. In some aspects, the other request may include the details of missing views.

Responsive to receiving the other request, the user device 202 may capture additional images and transmit them to the receiver 210. The processor 212 may then analyze the additional images to determine their quality and calculate a new quality score for the building portion.

In some aspects, the processor 212 may generate the building portion 3D scan/model based on the first plurality of images and/or the additional images, when the quality score is above the threshold. Specifically, the processor 212 may command the neural network model 218 to generate the building portion 3D model based on the images. The neural network model 218 may include mapping of a plurality of pre-stored images with different building portions and objects. The neural network model 218 may compare the first plurality of images and/or the additional images with the plurality of pre-stored images, identify building portions and objects corresponding to the first plurality of images and/or the additional images, and generate the building portion 3D model accordingly. For example, the plurality of pre-stored images may include images for kitchen, living room, washroom, bedroom, building exterior, cabinets, doors, walls and the like. Hence, when the first plurality of images includes one or more images of kitchen cabinets, the neural network model 218 may compare the one or more images with the plurality of pre-stored images and determine that the images correspond to kitchen cabinets.

In addition, the neural network model 218 may determine building portion attributes (and attributes of objects included in the building portion), based on the generated building portion 3D model. In some aspects, the building portion attributes may include dimensions of walls, doors, windows, furniture, etc. included in the building portion.

Responsive to identifying building portions (and objects), generating the building portion 3D model and determining the building portion attributes, the neural network model 218 may send names or identifiers of identified building portions (and objects), the generated building portion 3D model and the attributes to the processor 212. The names or identifiers of building portions may include names like “Kitchen”, “Kitchen door”, “Kitchen roof” and the like. In some aspects, the neural network model 218 may further segregate images based on different building portion sub-parts and/or objects and may share the segregated images to the processor 212. For example, the neural network model 218 may segregate images of floors, doors, cabinets, etc. from the first plurality of images and/or additional images and share the segregated images to the processor 212. In other aspects, the neural network model 218 may further segregate the images based on building portions such as kitchen, living room, washroom and the like.

Responsive to receiving the building portion/objects names or identifiers, the building portion 3D model, the building portion attributes and the segregated images from the neural network model 218, the processor 212 may fetch mapping of different building portions and job portions from the building and job portion database 226. The processor 212 may then determine job portions corresponding to the received building portions' names/identifiers, based on the mapping of the different building portions and job portions. For example, when the neural network model 218 determines from the first plurality of images that the building portion corresponds to kitchen and sends “kitchen” as a building portion identifier to the processor 212, the processor 212 may compare the “kitchen” identifier with identifiers included in the mapping of different building portions and job portions. Based on the comparison, the processor 212 may identify job portions associated with “kitchen” stored in the building and job portion database 226.

In some aspects, the processor 212 may transmit, via the transmitter 214, the identified job portions to the user device 202 to receive approval or inputs from the user 110 and receive user preferences on the identified job portions. For example, the processor 212 may transmit flooring, carpentry, electrical work, painting and the like to the user device 202. Response to receiving the job portions, the user 110 may approve all job portions or select one or more job portions from the received job portions. For example, the user 110 may select only carpentry work from the job portions transmitted by the processor 212 and may send the selection to the processor 212 (via the receiver 210). The processor 212 may be further configured to receive the selection/inputs from the user 110 on the job portions.

In other aspects, the processor 212 may identify the job portions using the second plurality of target building portion images. In particular, the processor 212 may fetch the first plurality of images and the second plurality of target building portion images from the memory 216 (i.e., from the building portion database 224 and the target building portions database 228). The processor 212 may then compare the first plurality of images with the second plurality of target building portion images and identify the job portions based on the comparison. In other words, the processor 212 may compare the images of the current building portion and the target building portion, and identify the job portions that may be required to be performed to convert the current building portion to the desired/target building portion. For example, if the processor 212 determines that flooring is same in the current building portion and the target building portion, then the processor 212 may not select “flooring” as a job portion for kitchen renovation.

Responsive to determining the job portions for the building portion renovation (e.g., kitchen renovation), the processor 212 may fetch the preset priority renovation order of the identified job portions for the building portion(s) from the building and job portion database 226. For example, the building and job portion database 226 may store mapping of “kitchen renovation” with job portions associated with kitchen, such as plumbing, carpentry, painting, etc., in a specific/relative order. The processor 212 may fetch the mapping and obtain the relative order of the identified job portions for the building portion(s). For example, if the user 110 selects “carpentry” and “electrical work” as the user's preferences, or if the processor 212 identifies “carpentry” and “electrical work” as the two required job portions based on the comparison of the first and second plurality of images, the processor 212 may identify relative order of performing “carpentry” and “electrical work” from the building and job portion database 226. Specifically, the processor 212 may compare “carpentry” and “electrical work” with job portions included in the preset priority renovation order and then identify the relative order of performing “carpentry” and “electrical work” based on the comparison.

The processor 212 may be further configured to obtain contractor profile from the contractor profile database 222. In some aspects, the processor 212 may match contractor profile with the selected/identified job portions to identify relevant contractors for corresponding job portions. For example, the processor 212 may identify electrical contractors for electrical work and carpenters for carpentry work.

In further aspects, the processor 212 may transmit, via the transmitter 214, the job portions and associated building portion dimensions to the identified third party/contractor (or plurality of third parties or contractors), which may enable the processor 212 to receive quotes for the respective job portion's completion. In some aspects, the transmitter 214 may transmit the job portions based on the relative renovation order. In some aspects, the processor 212 may assign timeline to each job portion's completion, based on the relative renovation order. In this case, the transmitter 214 may transmit the job portions to the contractors, along with respective timelines and building portion dimensions.

In further aspects, the receiver 210 may be further configured to receive the quotes from the contractors for corresponding job portions' completion. In addition, the receiver 210 may receive timelines to complete the respective job portions from the contractors. In response to receiving the quotes, the processor 212 may compare the quotes with a threshold value stored in the memory 216 or the user budget for renovation stored in the user profile database 220. The processor 212 may be further configured to select one or more contractors based on the quotes. The processor 212 may further assign the respective job portions to the selected contractors. In other aspects, the processor 212 may recommend the one or more contractors to the user 110 (e.g., by sending the recommendation to the user device 202) and the user 110 may select a contractor for the job portion(s).

In additional aspects, the user 110 may request renovation of multiple building portions in a single request. For example, the user 110 may send a request to the receiver 210 indication that the user 110 may want to renovate the kitchen, the washroom and the exterior building surface. Additionally, the user 110 may send multiple images of kitchen, washroom and the exterior building surface to the processor 212, via the receiver 210. In this case, the processor 212 may send the multiple images to the neural network model 218, which may segregate the images and identify building portions and attributes, by comparing/correlating the images with the plurality of pre-stored images, as described above. The neural network model 218 may store a mapping of the multiple images with the identified building portions in the memory 216 and may also share the mapping with the processor 212. Furthermore, the processor 212 may identify job portions corresponding to each building portion in the same manner as described above. Thereafter, the processor 212 may send the job portions and the building portion attributes to a plurality of contractors to receive quotes. In response to receiving quotes from the contractors, the processor 212 may select one or more contractors to perform the job portions, as described above.

A person ordinarily skilled in the art may appreciate that the present disclosure provides various advantages over conventional approaches of building renovation. For example, by using the renovation platform 200, the user 110 may save effort and time to get the estimation of cost for the renovation work, select contractors, share user preferences, manage contractors and other third parties (such as funding), monitor progress and the like. The contractors (and other third parties) may also save effort and time in measuring building portion dimensions (as the renovation platform 200 may perform the measurements), estimating cost, monitoring progress and the like.

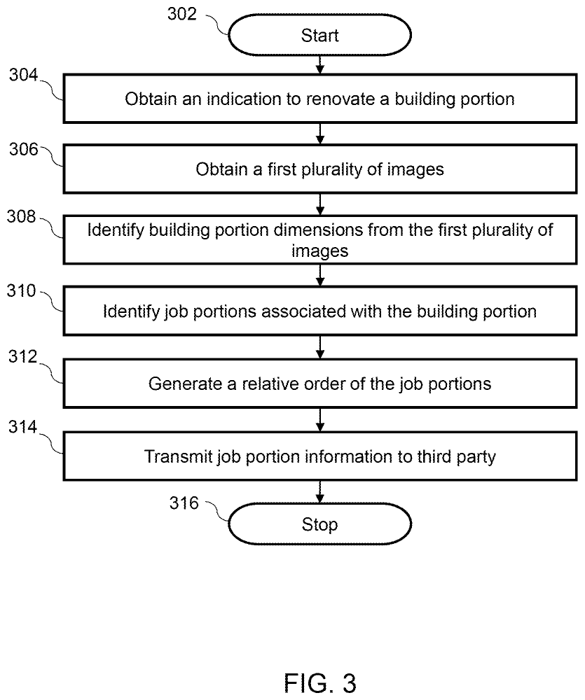

FIG. 3 depicts a flow diagram of an example method 300 for facilitating building renovation in accordance with the present disclosure. FIG. 3 may be described with continued reference to prior figures, including FIGS. 1 and 2. The following process is exemplary and not confined to the steps described hereafter. Moreover, alternative embodiments may include more or less steps that are shown or described herein and may include these steps in a different order than the order described in the following example embodiments.

Referring to FIG. 3, at step 302, the method 300 may commence. At step 304, the method 300 may include obtaining, by the processor 212, an indication to renovate building portion(s). The indication may be received in a request from the user device 202, which may be generated by the user 110. The building portion may be portion of a residential or commercial building including, but not limited to, kitchen, living room, bedroom, washroom, roof, building exterior, office space and the like. In some aspects, the building portion may include objects located in the building, such as cabinets, doors, windows, furniture, appliances and the like.

At step 306, the method 300 may include obtaining, by the processor 212, a first plurality of images associated with the building portion(s). The first plurality of images may include photographs, videos and their combination thereof. The processor 212 may obtain the first plurality of images from the receiver 210 or the memory 216.

At step 308, the method 300 may include identifying, by the processor 212, building portion(s) dimensions from the first plurality of images. In particular, the processor 212 (via the neural network model 218) may generate the building portion 3D model based on the first plurality of images, as described above. The processor 212, via the neural network model 218, may further determine the building portion attributes/dimensions based on the 3D model. In some aspects, when the first plurality of images includes images of a plurality of building portions, the processor 212 may first identify the plurality of building portions from the first plurality of images. In particular, the processor 212, via the neural network model 218, may correlate the first plurality of images with pre-stored building portion images (as discussed in conjunction with FIG. 2) and identify the building portions to be renovated.

At step 310, the method 300 may include identifying, by the processor 212, job portions associated with the building portion(s). As described above, the processor 212 may fetch building portions mapping with associated job portions from the building and job portion database 226. The processor 212 may be further configured to identify the job portions corresponding to the building portions based on the fetched mapping.

At step 312, the method 300 may include generating, by the processor 212, relative job portion order. The relative order may include a preset priority renovation order associated with the renovation portion. In particular, the processor 212 may fetch the relative job portion order from the memory 216 for the respective building portions, as described above.

At step 314, the method 300 may include transmitting, by the processor 212 (via the transmitter 214), information associated with the job portion to one or more third parties (contractors) based on the relative job portion order. The information may include the building portion dimensions. In particular, the processor 212 may fetch list of contractors (along with profiles) from the memory 216, match the list with the identified job portions, select one or more contractors to complete the job portion, and transmit the job portion information to the selected contractors. The method stops at step 316.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a feature, structure, or characteristic is described in connection with an embodiment, one skilled in the art will recognize such feature, structure, or characteristic in connection with other embodiments whether or not explicitly described.

Further, where appropriate, the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description and claims refer to particular system components. As one skilled in the art will appreciate, components may be referred to by different names. This document does not intend to distinguish between components that differ in name, but not function.

It should also be understood that the word “example” as used herein is intended to be non-exclusionary and non-limiting in nature. More particularly, the word “example” as used herein indicates one among several examples, and it should be understood that no undue emphasis or preference is being directed to the particular example being described.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Computing devices may include computer-executable instructions, where the instructions may be executable by one or more computing devices such as those listed above and stored on a computer-readable medium.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating various embodiments and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A method to facilitate building renovation, the method comprising:
obtaining, by a processor, an indication to renovate a building portion;
obtaining, by the processor, a first plurality of images associated with the building portion from a first user device;
identifying, by the processor, building portion dimensions based on the first plurality of images;
identifying, by the processor, job portions associated with the building portion based on the first plurality of images;
generating, by the processor, a relative renovation order of the job portions in response to job portions identification; and
transmitting, by the processor, information associated with the job portions to at least a third party device based on the relative renovation order, wherein the information comprises the building portion dimensions.

2. The method of claim 1, wherein obtaining the indication comprises receiving a request from a second user device to renovate the building portion.

3. The method of claim 1 further comprising:
calculating a score for the building portion based on the first plurality of images;
comparing the score with a threshold value;
determining whether the score is less than the threshold value; and
obtaining additional images of the building portion based on a determination that the score is less than the threshold value.

4. The method of claim 3 further comprising transmitting instructions to the first user device to provide the additional images.

5. The method of claim 1 further comprising:
obtaining a second plurality of target building portion images from the first user device;
comparing the first plurality of images with the second plurality of target building portion images; and
identifying the job portions based on the comparison.

6. The method of claim 1 further comprising:
obtaining a preset priority renovation order associated with the building portion from a memory;
comparing the job portions with the preset priority renovation order; and
generating the relative renovation order based on the preset priority renovation order.

7. The method of claim 1 further comprising:
obtaining the indication to renovate a plurality of additional building portions;
obtaining a third plurality of images associated with the plurality of additional building portions;
correlating the third plurality of images with a fourth pre-stored images;
identifying the plurality of additional building portions based on the correlation; and
identifying second job portions associated with the plurality of additional building portions based on the third plurality of images.

8. The method of claim 7 further comprising:
storing a mapping of the third plurality of images with respective building portions in a memory.

9. The method of claim 8 further comprising:
transmitting respective job portions to at least the third party device to provide quote for job portion completion;
receiving quotes from at least the third party device;
comparing the quotes with a threshold value; and
assigning the respective job portions to a third party based on the comparison.

10. The method of claim 1, wherein the building portion comprises at least one building portion object.

11. A renovation system comprising:
a receiver configured to:
receive an indication to renovate a building portion; and
receive a first plurality of images associated with the building portion from a first user device;
a processor communicatively coupled to the receiver;
a memory for storing executable instructions, the processor configured to execute the instructions to:
obtain the indication to renovate the building portion and the first plurality of images;
identify building portion dimensions based on the first plurality of images;
identify job portions associated with the building portion based on the first plurality of images; and
generate a relative renovation order of the job portions in response to job portions identification; and
a transmitter configured to transmit information associated with the job portions to at least a third party device based on the relative renovation order, wherein the information comprises the building portion dimensions.

12. The renovation system of claim 11, wherein the receiver is configured to receive the indication in a request from a second user device to renovate the building portion.

13. The renovation system of claim 11, wherein the processor is further configured to:
calculate a score for the building portion based on the first plurality of images;
compare the score with a threshold value;
determine whether the score is less than the threshold value; and
obtain additional images of the building portion based on a determination that the score is less than the threshold value.

14. The renovation system of claim 13, wherein the transmitter is further configured to transmit instructions to the first user device to provide the additional images.

15. The renovation system of claim 11, wherein the processor is further configured to:
obtain a second plurality of target building portion images from the first user device;
compare the first plurality of images with the second plurality of target building portion images; and
identify the job portions based on the comparison.

16. The renovation system of claim 11, wherein the processor is further configured to:
obtain a preset priority renovation order associated with the building portion from a memory;
compare the job portions with the preset priority renovation order; and
generate the relative renovation order based on the preset priority renovation order.

17. The renovation system of claim 11, wherein the processor is further configured to:
obtain the indication to renovate a plurality of additional building portions;
obtain a third plurality of images associated with the plurality of additional building portions;
correlate the third plurality of images with a fourth pre-stored images;
identify the plurality of additional building portions based on the correlation; and
identify second job portions associated with the plurality of additional building portions based on the third plurality of images.

18. The renovation system of claim 17, wherein the memory is configured to store a mapping of the third plurality of images with respective building portions in a memory.

19. The renovation system of claim 11, wherein the building portion comprises at least one building portion object.

20. A non-transitory computer-readable storage medium in a distributed computing system, the non-transitory computer-readable storage medium having instructions stored thereupon which, when executed by a processor, cause the processor to:
obtain an indication to renovate a building portion;
obtain a first plurality of images associated with the building portion from a first user device;
identify building portion dimensions based on the first plurality of images;
identify job portions associated with the building portion based on the first plurality of images;
generate a relative renovation order of the job portions in response to job portions identification; and
transmit information associated with the job portions to at least a third party device based on the relative renovation order, wherein the information comprises the building portion dimensions.
